(19) United States
(12) Patent Application Publication
(10) Pub. No.: US 2006/0279340 A1
(43) Pub. Date: Dec. 14, 2006

(54) Semiconductor integrated circuit device

(75) Inventor: Hiroshi Toyoshima, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/450,424

(22) Filed: Jun. 12, 2006

(30) Foreign Application Priority Data
Jun. 13, 2005 (JP) 2005-172851

(51) Int. Cl. H03B 1/00

(52) U.S. Cl. 327/112

(57) ABSTRACT

A dummy MOSFET is provided which is connected in common with the gate of an N channel output MOSFET that constitutes a CMOS output circuit and which is set so as to have a gate capacitance corresponding to a difference between a gate capacitance of a P channel output MOSFET that constitutes the CMOS output circuit and a gate capacitance of the N channel output MOSFET. An input capacitance of the N channel output MOSFET and an input capacitance of the P channel output MOSFET are set equal to each other.

### CROSS-REFERENCE TO RELATED APPLICATION

The present application claims priority from Japanese patent application No. 2005-172851 filed on Jun. 13, 2005, the content of which is hereby incorporated by reference into this application.

### BACKGROUND OF THE INVENTION

The present invention relates to a semiconductor integrated circuit device, and relates to a circuit technique suitable when applied to a semiconductor integrated circuit device, which is capable of performing a data transfer at a high frequency on a system.

With a view toward performing the transfer of data between a memory LSI (Large Scale Integration) and an MPU (Microprocessor) at high speed, for example, there is a need to perform impedance matching of a transmission system and suppress distortion of a transfer waveform by reflection. In a high-speed synchronous SRAM (Static Random Access Memory) product, there is known one having such specs that the impedance of an output driver is adjusted so as to become equal to the resistance value of a resistive element connected to dedicated LSI pins in order to perform impedance matching. The technique of adjusting output impedance has been disclosed in, for example, a patent document 1 (Japanese Unexamined Patent Publication No. Hei 10(1998)-242835). In the present publication, an output impedance control transistor and a through rate control transistor are provided separately. A short pulse is applied to the gate of the through rate control transistor to control a rise time, and an output voltage level is determined by the output impedance control transistor. As an example of a CMOS output circuit, there is known a non-patent document 1 (“Design of CMOS VLSI” published by BAIFUKAN Co., Ltd., supervised by Takuo Kanno and edited by Tetsuya Iizuka, P. 146, FIG. 4, 72).

### SUMMARY OF THE INVENTION

In a CMOS output circuit, W (channel width) sizes are determined such that the currents of a P channel output MOSFET and an N channel output MOSFET become equal to each other. Since, however, the P channel output MOSFET and the N channel output MOSFET are different twice or so in current ratio per unit W size, the W sizes of the P channel output MOSFET and the N channel output MOSFET become different sizes spontaneously.

With improvements in operating frequency, an effective time of output data is very short considering even output's variation times in a high-speed SRAM. It is therefore important to reduce variations in the output rise time (high level output) and output fall time (low level output) for the purpose of ensuring the effective period of the output data. However, the W size of the P channel output MOSFET and the W size of the N channel output MOSFET are different as mentioned above. Since drive buffers for driving the gates of these output MOSFETs are inevitably different in size, variations occur in the output rise time and output fall time due to variations in drive capacity of each drive buffer and the difference in gate capacitance between the output MOSs, which is caused by the difference in W size between the output MOSS. Further, even when di/dt of an output MOSFET current for reducing noise caused by each of the output MOSs is adjusted, its control is complicated and hence the high-speed SRAM comes under the influence of device's process variations.

An object of the present invention is to provide a semiconductor integrated circuit device equipped with an output circuit capable of ensuring an effective output data period at a high frequency by simple control. Another object of the present invention is to provide a semiconductor integrated circuit device capable of enhancing a data transfer rate. The above, other objects and novel features of the present invention will become apparent from the description of the present specification and the accompanying drawings.

Summaries of a representative one of the inventions disclosed in the present application will be explained in brief as follows: A dummy MOSFET is provided which is connected in common with the gate of an N channel output MOSFET that constitutes a CMOS output circuit and which is set so as to have a gate capacitance corresponding to a difference between a gate capacitance of a P channel output MOSFET that constitutes the CMOS output circuit and a gate capacitance of the N channel output MOSFET. An input capacitance of the N channel output MOSFET and an input capacitance of the P channel output MOSFET are set equal to each other.

An effective output data period can be ensured by reducing variations in the rise and fall times of an output signal. A contribution to an improvement in data transfer rate can be made. Further, such an adjustment that an output delay time can be minimized while output noise is being reduced, can also be made.

### BRIEF DESCRIPTION OF THE DRAWINGS

FIG. 1 is a circuit diagram showing one embodiment of an output circuit according to the present invention;

FIG. 2 is a circuit diagram illustrating another embodiment of an output circuit according to the present invention;

FIG. 3 is a circuit diagram depicting one embodiment of a drive circuit which forms a drive signal DQP of a P channel output MOSFET;

FIG. 4 is a circuit diagram showing one embodiment of a drive circuit which forms a drive signal DQN of an N channel output MOSFET;

FIG. 5 is a block diagram illustrating one embodiment of an output circuit provided in a semiconductor integrated circuit device according to the present invention;

FIG. 6 is a device layout diagram depicting one embodiment of an output MOS according to the present invention;

FIG. 7 is a device layout diagram showing another embodiment of an output MOS according to the present invention;

FIG. 8 is an output waveform diagram for describing the present invention;

FIG. 9 is a waveform diagram for describing the relationship between di/dt of an output waveform and output noise;

FIG. 10 is a block diagram illustrating one embodiment of a synchronous SRAM equipped with an output circuit according to the present invention;

FIG. 11 is a block diagram showing one embodiment of an impedance control code generating circuit;

FIG. 12 is a circuit diagram illustrating another embodiment of an output circuit according to the present invention; and

FIG. 13 is a waveform diagram for explaining the output operation of the output circuit according to the present invention.

### DETAILED DESCRIPTION OF THE PREFERRED EMBODIMENTS

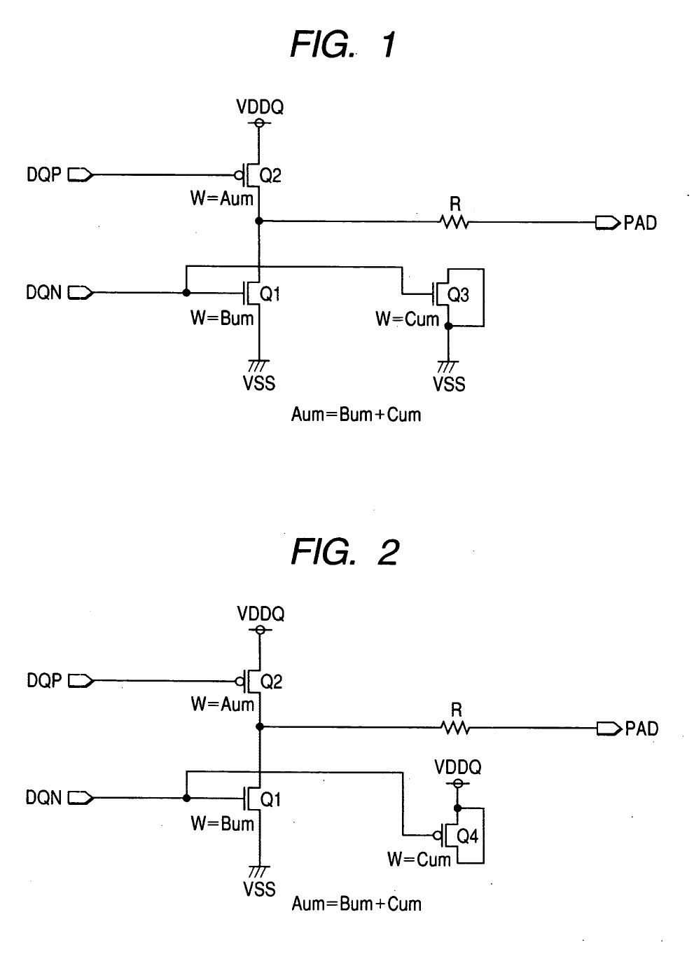

A circuit diagram illustrating one embodiment of an output circuit according to the present invention is shown in FIG. 1. The output circuit comprises a P channel output MOSFET Q2 which forms a high level output signal corresponding to a power supply voltage VDDQ, and an N channel output MOSFET Q1 which forms a low level output signal corresponding to a circuit's ground potential VSS. The drains of the output MOSFETs Q1 and Q2 are connected in common and connected to an output terminal PAD via a resistor R.

When a W size (channel width) of the P channel output MOSFET Q2 is assumed to be Aum and a W size of the N channel output MOSFET Q1 is assumed, to be Bum, an N channel dummy MOSFET Q3 whose W size is assumed to be Cum, is connected to the N channel output MOSFET Q1. That is, the gate of the dummy MOSFET Q3, is connected to the gate of the N channel output MOSFET Q1, whereas although not restricted in particular, its source and drain are supplied with the ground potential VSS. The W sizes of the MOSFETs Q1 through Q3 are in a relationship of Aum=Bum+Cum. Since the MOSFETs Q1 through Q3 are formed equally in L size (channel length), the meaning of setting the W-size relationship to Aum=Bum+Cum resides in that a gate capacitance of the MOSFET Q2 corresponding to an input capacitance on the P channel side and the sum of gate capacitances of the MOSFETs Q1 and Q3 corresponding to an input capacitance on the N channel side are set equal to each other.

A circuit diagram of another embodiment of an output circuit according to the present invention is shown in FIG. 2. In the present embodiment, the dummy MOSFET shown in FIG. 1 is substituted with a P channel MOSFET Q4. That is, the gate of the P channel MOSFET Q4 is connected to the gate of the N channel MOSFET Q1 similar to FIG. 1. Although not restricted in particular, the source and drain of the dummy MOSFET Q4 are supplied with a power supply voltage VDDQ. Even when such a P channel MOSFET Q4 is used, such a relationship that Aum=Bum+Cum is established in a manner similar to the above. An input capacitance on the P channel side and an input capacitance on the N channel side are set equal to each other. The present embodiment is similar to the embodiment shown in FIG. 1 in other configuration.

While the embodiments shown in FIGS. 1 and 2 respectively show the configurations in which the resistors R are inserted in series with the output MOSFETs Q1 and Q2, this is done to consider that output impedance control of the output circuit is carried out as will be described later. That is, in such a configuration that a plurality of unit circuits are provided in parallel with their corresponding output terminals PADs with such an output circuit as shown in FIG. 1 or 2 as the unit circuit, nonlinearity appears even when the number of parallel-connected MOSFETs is controlled to perform output impedance control with nonlinearity of on resistance values of the MOSFETs Q1 and Q2. Therefore, such a configuration that the resistor R is inserted in series with the output MOSFETs Q1 and Q2, is taken to allow such a circuit to function so as to correct the nonlinearity of the on resistance values of such MOSFETs Q1 and Q2. In FIGS. 1 and 2, the gates of the output MOSFETs Q1 and Q2 are respectively supplied with drive signals DQN and DQP formed by such drive circuits as to be explained next.

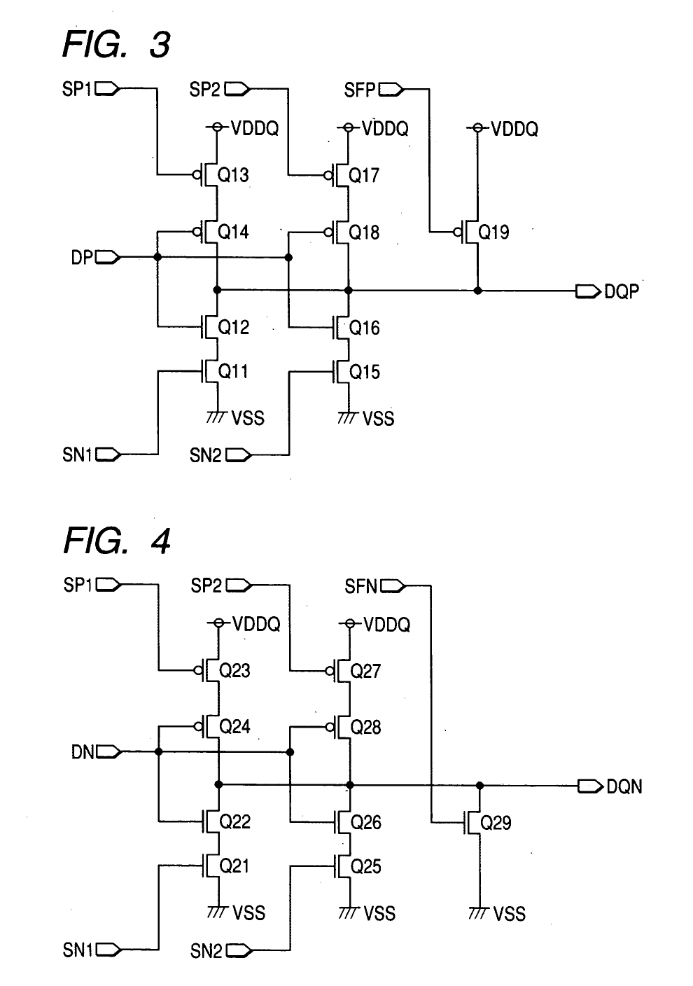

A circuit diagram illustrating one embodiment of the drive circuit which forms the drive signal DQP of the P channel output MOSFET is shown in FIG. 3. The output signal DQP of the drive circuit according to the present embodiment is supplied to the gates of the P channel output MOSFETs Q2 shown in FIGS. 1 and 2. In the present embodiment, the drive circuit is set so as to have the function of being capable of always bringing the output MOSFET to an off state in order to enable the output impedance control. That is, an output pull-up MOSFET fixes the drive signal DQP to a high level like the power supply voltage VDDQ to enable the output MOSFET Q2 to be brought to the off state on a steady basis. Namely, the output impedance can be made large by setting a steadily turned-off output MOSFET of output MOSFETs provided in plural form.

In order to enable through rate control of the output circuit, the drive circuit is provided in plural form, i.e., two first and second drive circuits are provided in the same figure. An N channel MOSFET Q12 and a P channel MOSFET Q14 constitute the first drive circuit formed so as to have predetermined current drive capacity. A data signal DP is supplied to the gates of the MOSFETs Q12 and Q14. The drains of these MOSFETs Q12 and Q14 are connected to an output line for the output signal DQP. An N channel MOSFET Q11 is provided between the source of the N channel MOSFET Q12 and a circuit's ground potential VSS. A P channel MOSFET Q13 is provided between the P channel MOSFET Q14 and the power supply voltage VDDQ. These MOSFETs Q11 and Q13 are set so as to have current supply capacities sufficiently larger than those of the MOSFETs Q12 and Q14 that constitute the first drive circuit. A drive current of the first drive circuit is exclusively determined by the MOSFETs Q12 and Q14.

An N channel MOSFET Q16 and a P channel MOSFET Q18 constitute the second drive circuit formed so as to have a predetermined current drive capacity. The gates of the MOSFETs Q16 and Q18 are supplied with the data signal DP in common. The drains of these MOSFETs Q16 and Q18 are connected in common with the output line for the output signal DQP. An N channel MOSFET Q15 is provided between the source of the N channel MOSFET Q16 and the ground potential VSS. A P channel MOSFET Q17 is provided between the P channel MOSFET Q18 and the power supply voltage VDDQ. These MOSFETs Q15 and Q17 are set so as to have current supply capacities sufficiently larger than those of the MOSFETs Q16 and Q18 that constitute the second drive circuit. A drive current of the second drive circuit is exclusively determined by the MOSFETs Q16 and Q18. A pull-up MOSFET comprising a P channel MOSFET Q19 is provided between the output line for the output signal DQP and the power supply voltage VDDQ.

A circuit diagram illustrating one embodiment of the drive circuit which forms the drive signal DQN of the N channel output MOSFET is shown in FIG. 4. As the drive circuit according to the present embodiment, one having the same configuration as the drive circuit having the P channel output MOSFETs shown in FIG. 3 is used corresponding to the setting of equalizing the input capacitances of the output MOSFETs by the insertion of the dummy MOSFETs as described above. That is, the output signal DQN of the drive circuit is supplied to the gate of the N channel output MOSFETs Q1 shown in FIGS. 1 and 2. Even in the present embodiment, the drive circuit is set so as to have the function of being able to always bring the corresponding output MOSFET to an off state in order to enable output impedance control in like manner. That is, the drive signal DQN is fixed to a low level like a circuit's ground potential VSS by an output pull-up MOSFET to make it possible to bring the output MOSFET Q1 to an off state on a stationary basis. Namely, the output impedance can be made large by setting the steadily turned-off output MOSFET of output MOSFETs provided in plural form.

In order to enable through rate control of the output circuit in a manner similar to the P channel side, the drive circuit is provided in plural form, i.e., two first and second drive circuits are provided in the same figure. An N channel MOSFET Q22 and a P channel MOSFET Q24 constitute the first drive circuit formed so as to have predetermined current drive capacity. A data signal DP is supplied to the gates of the MOSFETs Q22 and Q24. The drains of these MOSFETs Q22 and Q24 are connected to an output line for the output signal DQN. An N channel MOSFET Q21 is provided between the source of the N channel MOSFET Q22 and the circuit's ground potential VSS. A P channel MOSFET Q23 is provided between the P channel MOSFET Q24 and a power supply voltage VDDQ. These MOSFETs Q21 and Q23 are set so as to have current supply capacities sufficiently larger than those of the MOSFETs Q22 and Q24 that constitute the first drive circuit. A drive current of the first drive circuit is exclusively determined by the MOSFETs Q22 and Q24.

An N channel MOSFET Q26 and a P channel MOSFET Q28 constitute the second drive circuit formed so as to have predetermined current drive capacity. The gates of the MOSFETs Q26 and Q28 are supplied with the data signal DP in common. The drains of these MOSFETs Q26 and Q28 are connected in common with the output line for the output signal DQN. An N channel MOSFET Q25 is provided between the source of the N channel MOSFET Q26 and the ground potential VSS. A P channel MOSFET Q27 is provided between the P channel MOSFET Q28 and the power supply voltage VDDQ. These MOSFETs Q25 and Q27 are set so as to have current supply capacities sufficiently larger than those of the MOSFETs Q26 and Q28 that constitute the second drive circuit. A drive current of the second drive circuit is exclusively determined by the MOSFETs Q26 and Q28. A pull-down MOSFET comprising an N channel MOSFET Q29 is provided between the output line for the output signal DQN and the power supply voltage VDDQ.

Assuming that the operating currents of the first drive circuits are 1 in FIGS. 3 and 4; the operating currents of the second drive circuits are respectively formed twice as large as the above operating currents, like 2, for example. The gates of the P channel MOSFETs Q13 and Q17 and Q23 and Q27 are respectively supplied with control signals SP1 and SP2. The gates of the N channel MOSFETs Q11 and Q15 and Q21 and Q25 are respectively supplied with control signals SN1 and SN2. And the gates of the MOSFETs Q19 and Q29 are respectively supplied with control signals SFP and SFN.

When the control signals SP1 and SP2 are respectively set to a select level corresponding to a low level, and the control signals SN1 and SN2 are respectively set to a select level corresponding to a high level, the first and second drive circuits are respectively brought into an operating state so that a large drive current like 1+2=3 can be formed. When the control signal SP1 is set to the high level, the control signal SP2 is set to the low level, the control signal SN1 is set to the low level, and the control signal SN2 is set to the high level, the first drive circuit is brought into an non-operating state (output high impedance) and hence the second drive circuit can form an intermediate drive current like 2. When the control signal SP1 is set to the low level, the control signal SP2 is set to the high level, the control signal SN1 is set to the high level, and the control signal SN2 is set to the low level, the second drive circuit is brought into the non-operating state (output high impedance) and hence the first drive circuit is capable of forming a small drive current like 1. With such three-stage current setting, the time required for the gate signal of the corresponding output MOSFET to rise/fall can be set. That is, it is possible to control through rates.

When the control signals SP1 and SP2 are respectively set to the high level and the control signals SN1 and SN2 are respectively set to the low level in the drive circuit according to the present embodiment, the first and second drive circuits are respectively brought into the non-operating state (output high impedance), so that the drive current reaches zero. Thus, the control signal SFP is brought to the low level to turn on the MOSFET Q19, so that the output signal DQP is fixed to the high level to bring the output MOSFET Q2 into an off state. With the setting of the output MOSFET per se to the off state in this way, the number of the output MOSFETs operated as described above can be changed and output impedance control is enabled.

In the present embodiment, the input capacitances of the P channel output MOSFET and the N channel output MOSFET are set equal to each other as mentioned above. Therefore, circuits identical in configuration to each other can be used as the drive circuits. Consequently, even though process variations occur in elemental devices that constitute the drive circuits, variations in the drive currents are brought to the same direction in the drive circuit for forming the drive current of the P channel MOSFET and the drive circuit for forming the drive current of the N channel MOSFET, and hence compensation for the process variations is made when seen from the viewpoint of an effective output data period.

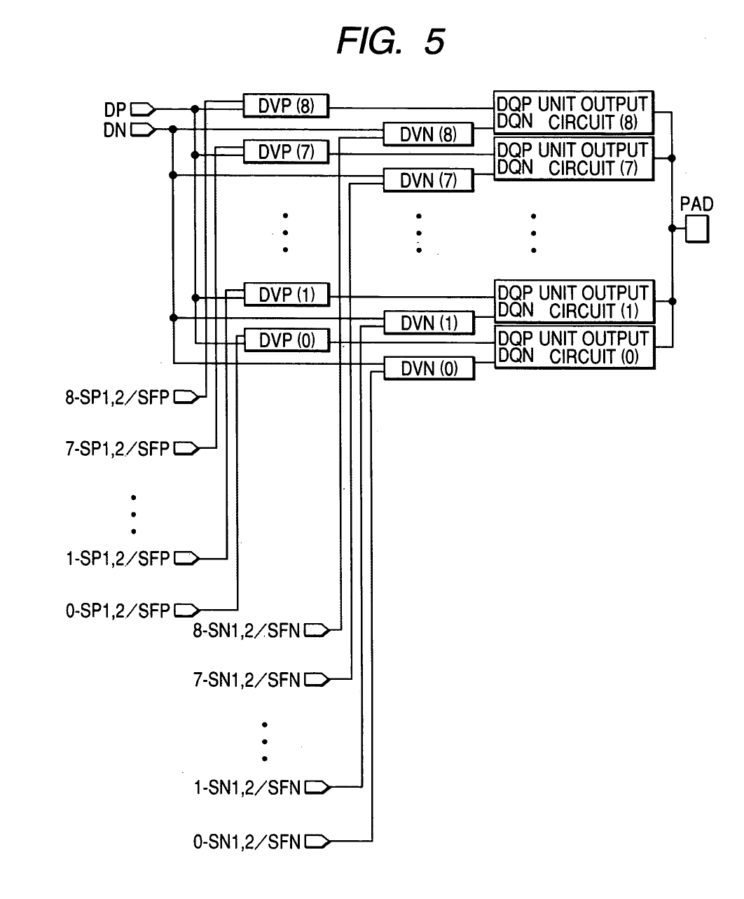

A block diagram illustrating one embodiment of an output circuit provided in a semiconductor integrated circuit device according to the present invention is shown in FIG. 5. In the present embodiment, unit output circuits (0) through (8) corresponding to 9 sets in total are provided at one output terminal PAD. In the same figure, the unit output circuits (0) and (1), and (7) and (8) of the unit output circuits (0) through (8) are illustratively shown as representatives. Of the nine unit output circuits (0) through (8), the unit output circuit (0) is of such an output circuit as to have standard output impedance, whereas the remaining unit output circuits (1) through (8) are used for output impedance adjustment. N channel drive circuits DVN (0) through (8) and P channel drive circuits DVP (0) through (8) are respectively provided in association with drive signals (input terminals) DQP of P channel output MOSFETs of the above 9 sets of unit output circuits (1) through (8) and drive signals (input terminals) DQN of N channel output MOSFETs thereof. Thus, the drive circuits corresponding to 2×9=18 are provided as a whole. In the drive circuits DVN (0) through (8) and the drive circuits DVP (0) through (8), their corresponding ones are set identical to one another in configuration.

While the unit output circuit (0) is formed of output MOSFETs each having such a size that each of them has a standard output impedance, it is also virtually provided with such dummy MOSFETs that input capacitances on the P channel output MOSFET side and the N channel output MOSFET side become equal to each other. The unit output circuits (1) through (8) may be respectively set equal to one another in configuration. However, in order to enable a wide range of settings by a small number of control signals, the unit output circuits (1) through (8) are formed of MOSFETs different in size, for example. Even in this case, the unit output circuits are respectively provided with such dummy MOSFETs that input capacitances on the P channel output MOSFET side and the N channel output MOSFET side become equal in the same manner as described above. In response to the magnitudes of the input capacitances of such unit output circuits (0) through (8), drive currents of the drive circuits DVN (0) through DVN (8) and DVP (0) through DVP (8) are also set so as to supply such currents that they are brought to, for example, such three types through rates as mentioned above.

When the unit output circuit (0) is configured of the output MOSFETs each having such a size that each of them has the standard output impedance, control signals SFN and SFP supplied to the drive circuits DVN (0) and DVP (0) corresponding thereto become unnecessary. The pull-down MOSFET and the pull-up MOSFET become unnecessary too. However, if the control signals SFN and SFP and the pull-down and pull-up MOSFETs are provided as in the embodiment shown in the same figure, it is then convenient when an output terminal PAD is forcibly brought to high impedance due to some reasons.

A data signal DP is supplied in common as data inputs of the eight P channel drive circuits DVP (0) through DVP (8). A data signal DN is supplied in common as data inputs of the eight N channel drive circuits DVN (0) through DVN (8). When the output terminal PAD is used for input/output sharing and the corresponding output circuit is brought to the output high impedance upon its input operation, the data signals DP and DN are set to such a level that the P channel MOSFET Q2 is brought to the off state in accordance with an output enable signal and such a level that the N channel output MOSFET Q1 is brought to the off state in accordance with the output enable signal, respectively.

On the other hand, control signals 1-SN1, 2/SFN, 1-SP1 and 2/SFP inputted to the drive circuits DVN (1) through DVN (8) and DVP (1) through DVP (8) are formed by impedance control codes and through rate control codes to be described later regardless of the above data signals DP and DN, and thereby combinations of the operated output MOSFETs and adjustments to drive currents for driving the same are carried out.

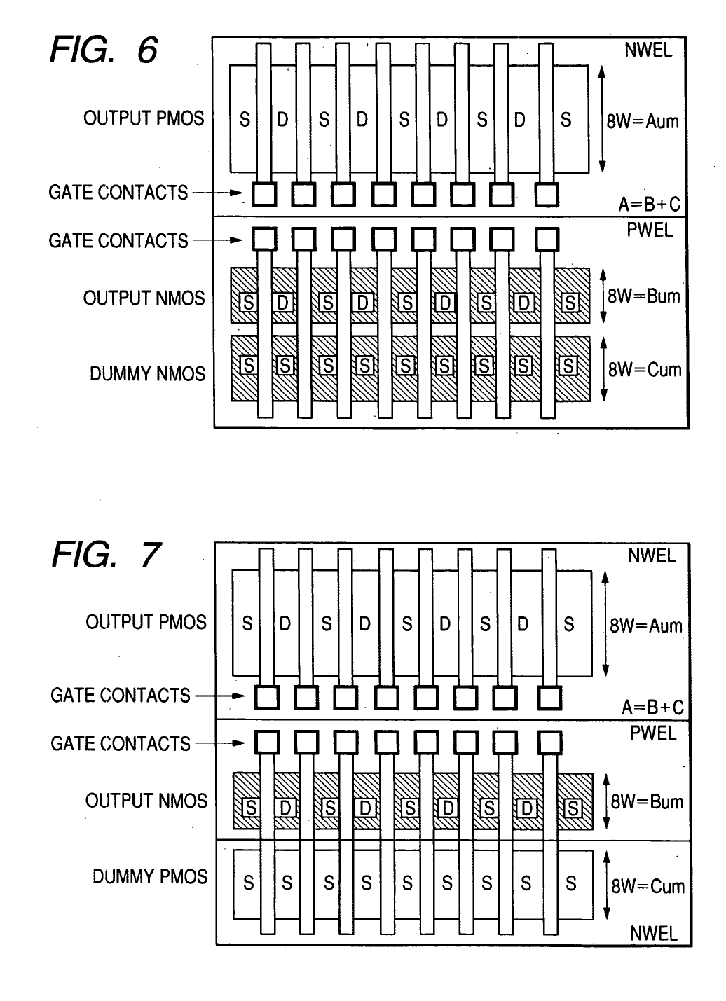

A device layout diagram illustrating one embodiment of a unit output circuit is shown in FIG. 6. Although not restricted in particular, the unit output circuit shown in the same figure corresponds to the unit output circuit (8) shown in FIG. 5. In the present embodiment, eight P channel MOSFETs (output PMOSs), eight N channel MOSFETs (output NMOSs) and eight dummy MOSFETs (dummy NMOSs) are shown.

The P channel MOSFETs (output PMOSs) are provided in an N type well region NWEL. In the N type well region NWEL, the eight MOSFETs are formed in which sources S are disposed at both ends and drains D and sources S are alternately disposed with eight gates interposed thereamong. Thus, since a W size of one MOSFET is ⅛, the output PMOSs are set to a size like 8W=Aum. The N channel MOSFETs (output NMOSs) are provided in a P type well region PWEL. In the P type well region PWEL, the eight MOSFETs are formed in which sources S are disposed at both ends and drains D and sources S are alternately disposed with eight gates interposed thereamong. Thus, since a W size of one MOSFET is ⅛, the output NMOSs are set to a size like 8W=Bum. In the same P type well region PWEL as described above, the eight dummy MOSFETs (dummy NMOSs) are formed in which sources S are disposed at both ends in the same manner as the output NMOSs and drains D and sources S are alternately disposed with eight gates formed integrally with the output NMOSs being interposed thereamong. The dummy MOSFETs are also set to a size like 8W=Cum. And the relationship between the sizes A, B and C is represented like A=B+C as illustrated in FIG. 1.

A device layout diagram showing another embodiment of a unit output circuit is shown in FIG. 7. Although not restricted in particular, output MOSs shown in the same figure correspond to the unit output circuit (8) shown in FIG. 5. In the present embodiment, eight P channel MOSFETs (output PMOSs), eight N channel MOSFETs (output NMOSs) and eight dummy MOSFETs (dummy PMOSs) are shown. That is, there is shown an example in which dummy MOSFETs and P channel MOSFETs are used as in the embodiment shown in FIG. 2.

In the present embodiment, an N type well region for the dummy MOSFETs is formed adjacent to a P type well region PWELL formed with the output NMOSs. In the N type well region, the eight dummy MOSFETs (dummy PMOSs) are formed in which drains D and sources S are alternately disposed with eight gates formed integrally with the output NMOSs being interposed thereamong. The dummy MOSFETs are also set to a size like 8W=Cum. And the relationship between the sizes A, B and C is represented like A=B+C as illustrated in FIG. 2. As an alternative to the present embodiment, one may be adopted wherein the dummy PMOSs are formed in the same N type well region as the output PMOSs.

In the unit output circuits (7) through (1) shown in FIG. 5, although not restricted in particular, the P channel MOSFET and the N channel MOSFET and dummy MOSFET are respectively constituted of (7) to (1) in number. In addition to it, the output MOSs (7) through (1) may be formed so as to have binary weights. For example, the unit output circuit (6) is constituted of the P channel MOSFETs and the N channel MOSFETs and dummy MOSFETs respectively corresponding to four in number, the unit output circuit (5) is constituted of the P channel MOSFETs and the N channel MOSFETs and dummy MOSFETs respectively corresponding to two in number, and the unit output circuit (4) is constituted of the P channel MOSFET and the N channel MOSFET and dummy MOSFET respectively corresponding to one in number.

And the unit output circuit (3) is constituted of the P channel MOSFET and the N channel MOSFET and dummy MOSFET respectively corresponding to ½ (channel width W: ½) in number. The unit output circuit (2) is constituted of the P channel MOSFET and the N channel MOSFET and dummy MOSFET respectively corresponding to ¼ (channel width W: ¼) in number. The unit output circuit (1) is constituted of the P channel MOSFET and the N channel MOSFET and dummy MOSFET respectively corresponding to ⅛ (channel width W: ⅛) in number.

Even in the case of the formation of the MOSFETs in any W size, the gate areas are held in the relationship like A=B+C, and the dummy MOSFETs are provided in such a manner that the input capacitance on the P channel output MOSFET side and the input capacitance on the N channel output MOS side become equal to each other. Drive currents of the first and second drive circuits, i.e., the sizes of the MOSFETs for the first and second drive circuits are set in accordance with the input capacitance on the dummy MOSFET side.

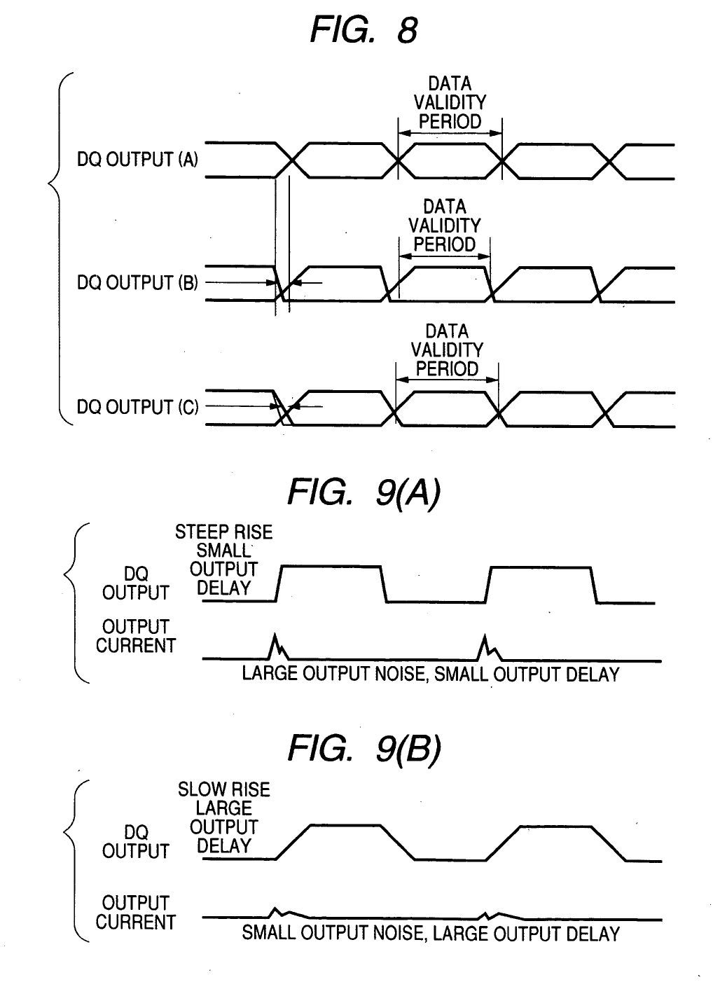

An output waveform diagram for describing the present invention is shown in FIG. 8. A DQ output (A) shows an ideal waveform example where no variations or fluctuations occur in the rising edge/falling edge of a high level/low level of an output signal. In such an ideal waveform, a data validity period becomes the longest and a high frequency operation short in clock cycle is also enabled. On the other hand, a DQ output (B) is as follows: The input capacitance on the N channel MOSFET side is small because no dummy MOSFETs are connected. Thus, when the P channel output MOSFETs and the N channel output MOSFETs are driven at the same drive current, the time required to fall from the high level to the low level becomes fast relative to the rising edge from the low level to the high level. As a result, the time Δt taken for variations in output rising edge/falling edge is taken long, and a data validity period is determined by a high-level output period corresponding to the worst side, thus making the data validity period short. Therefore, this is not adequate to a high speed operation.

A DQ output (C) is as follows: When the P channel output MOSFETs and the N channel output MOSFETs, are driven at the same drive current in a state in which the dummy MOSFETs (dummy capacitances) are connected to increase the input capacitance on the N channel MOS side as in the invention of the present application, the time required to fall from the high level to the low level becomes later than the rising edge of a gate voltage by the provision of the dummy MOSFETs, so that a change in output signal also becomes slow. Therefore, the time Δt taken for variations in output rising edge/falling edge is taken short and correspondingly a data validity period can be made long as compared with (B). In the present invention, the dummy MOSFETs are used to allow the input capacitance on the N channel output MOS side to coincide with the input capacitance on the P channel output MOS side, whereby the DQ output can be brought close to the ideal output waveform as indicated by the above (A). Thus, the data validity period is made long and a high frequency operation short in clock cycle is enabled.

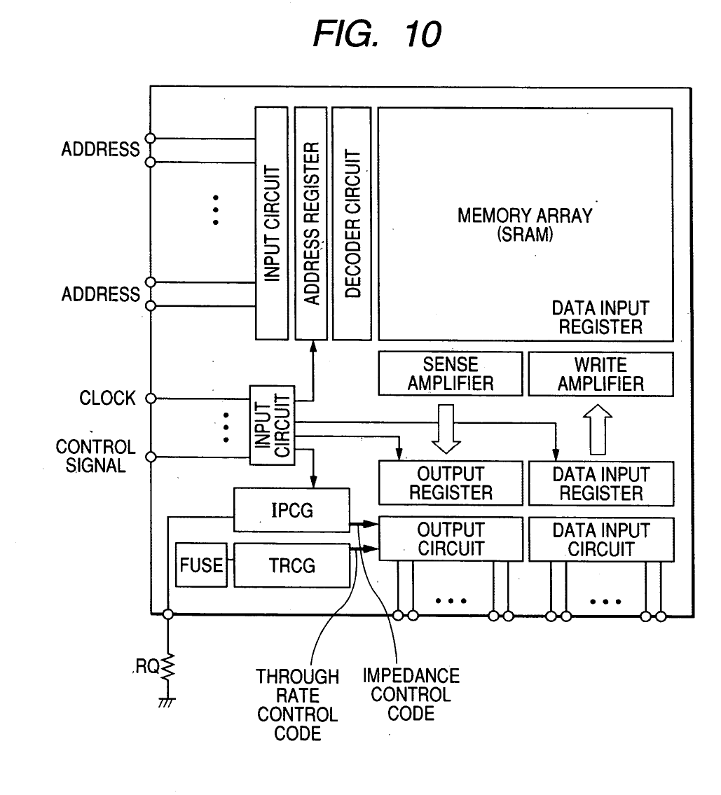

A waveform diagram for describing the relationship between di/dt of an output waveform and output noise is shown in FIG. 9. In FIG. 9(A), an output delay time becomes short when the time required for a DQ output to rise/fall is made steep, whereas output noise becomes large. As a result of the fact that signal fetching is delayed until an output signal level is stabilized in avoidance of the influence of such noise, a substantial signal transmission rate is delayed. FIG. 9(B) shows a case in which the time required for a DQ output to rise/fall is made slow to suppress output noise. Although an output delay time is made long in this case, the signal fetching is enabled without the influence of noise and hence the substantial signal transmission rate can be made fast.

In the output circuit according to the present embodiment, the number of the output MOSFETs is adjusted in addition to the prolongation of the data validity period by the provision of the above dummy MOSFETs to thereby match the output impedance to the characteristic impedance of a signal line through which the output signal is transferred. Therefore, the occurrence of reflection noise can be suppressed and di/dt of the output waveform, i.e., a through rate can be set by the above first and second drive circuits, thus making it possible to suppress the occurrence of the output noise and carry out high-speed signal transfer.

A block diagram illustrative of one embodiment of a synchronous SRAM equipped with an output circuit according to the present invention is shown in FIG. 10. An input circuit receives an address signal therein. Based on the address signal, a memory cell in a memory array is selected through an address register and a decoder circuit. A data signal outputted from the selected memory cell is amplified by a sense amplifier, followed by reaching the corresponding output circuit via an output register. The output circuit outputs the signal to the outside. The output circuit is configured of such a circuit as shown in FIG. 5. As described above, the rise/fall waveforms of the output of the output circuit are transitioned approximately equally to ensure the data validity period of the output, and adjustments to output impedance and a through rate are also made.

An output through rate control code generator TRCG receives a signal of a laser fuse FUSE mounted in, for example, a chip and generates output through rate control codes, followed by supply to control terminals SP1 and SP2 and SN1 and SN2 of drive circuits DVP and DVN in the output circuit. In the drive circuits DVP and DVN, their drive capacities change according to the output through rate control codes (SP1, SP2/SN1, SN2), and the rise/fall speeds of the output circuit can be adjusted. As a result, output noise can be reduced.

An impedance control code generator IPCG generates impedance control codes for output MOSs in accordance with a reference external resistor RQ connected to the outside, for example. The impedance control codes respectively correspond to the control signals 1 through 8 in the example illustrative of the drive circuits shown in FIG. 5 and are combined with the output through rate control codes (SP1 and SP2) to form control codes like 1-SN1, 2/SFP to 8-SP1, 2/SFP and 1-SN1, 2/SFN to 8-SN1, 2/SFN. When, for example, the control signal 1 is brought to non-selection, the control signals 1-SP1, 2/SFP are represented as follows when explained using the drive circuits shown in FIG. 3. The control signals SP1 and SP2 are both rendered high in level and the signal SFP is rendered low in level. As a result, the P channel output MOSFETs corresponding thereto are brought into an off state. And the control signals 1-SN1, 2/SFN are represented as follows when explained using the drive circuits shown in FIG. 4. The control signals SN1 and SN2 are both rendered low in level and the signal SFN is rendered high in level, so that the N channel MOSFETs corresponding thereto are brought into an off state.

On the other hand, when the control signal 1 is brought to selection, the control signals 1-SP1, 2/SFP are represented as follows when explained using the drive circuits shown in FIG. 3. The control signals SP1 and SP2 are both rendered low in level and the signal SFP is rendered high in level. And the control signals 1-SN1, 2/SFN are represented as follows when explained using the drive circuits shown in FIG. 4. The control signals SN1 and SN2 are both rendered high in level and the signal SFN is rendered low in level. Therefore, output DQP and DQN are formed in response to their corresponding data inputs DP and DN, so that a tristate output operation including output high impedance is performed. The control signals 2 through 8 are hereinafter similar to the above and the number of output MOSFETs operated corresponding to such control signals 1 through 8 is determined. Thus, the active number of output MOSs is controlled by the impedance control codes and furthermore the impedance of each output MOS can be controlled.

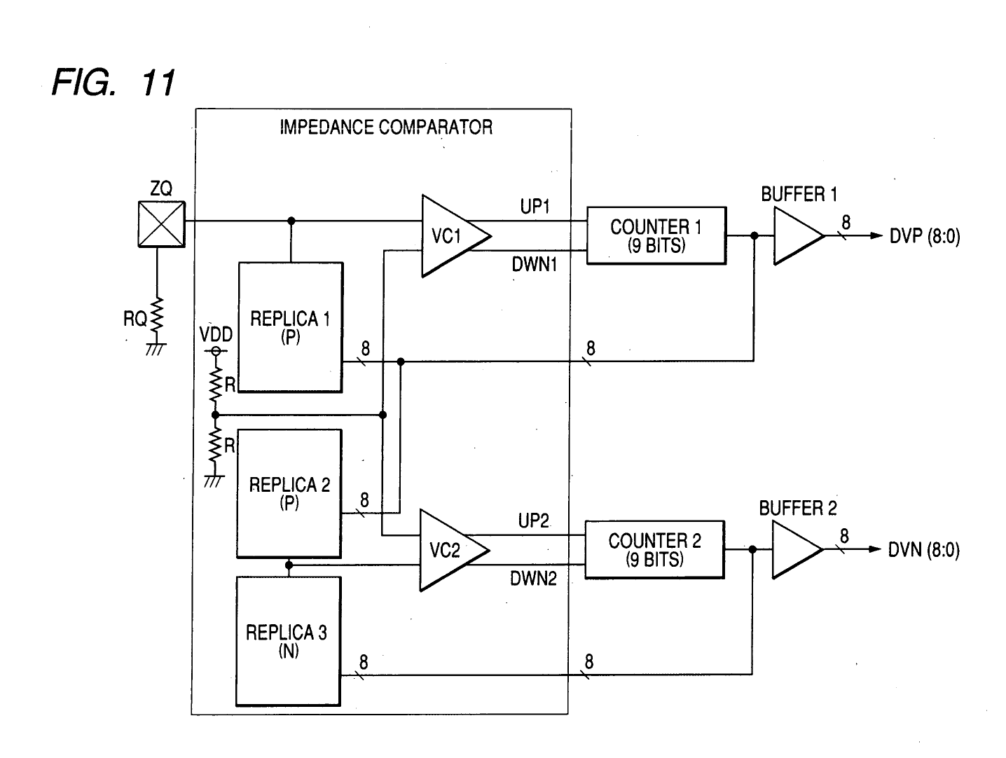

A block diagram illustrating one embodiment of the impedance control code generator shown in FIG. 10 is shown in FIG. 11. An external resistor RQ is connected to an external terminal ZQ. The resistor RQ and a replica 1 are connected in series. The replica 1 is a circuit corresponding to the P channel output MOS shown in FIG. 5. A voltage divided by the resistor RQ and the replica 1 is compared with a reference voltage of VDD/2 formed using resistors R by a voltage comparator VC1. Thus, an up signal UP1 or a down signal DWN1 is formed and counted by a counter 1. This counted output is transferred to the replica 1 as a feedback signal, so that its impedance is controlled.

A replica 2 is made identical in configuration to the replica 1, and its impedance control is performed by the feedback signal. The replica 2 and a replica 3 are connected in series. The replica 3 is a circuit corresponding to the N channel output MOS shown in FIG. 5. A voltage divided by the replica 3 and the replica 2 is compared with a reference voltage of VDD/2 formed using the resistors R by a voltage comparator VC2. Thus, an up signal UP2 or a down signal DWN2 is formed and counted by a counter 2. This counted output is transferred to the replica 3 as a feedback signal, so that its impedance is controlled. Thus, the resistor RQ and the replicas 1 and 3 become equal to one another in resistance value. Count values DVP (8:0) of the counter 1 and count values DVN (8:0) of the counter 2, which control the resistance values of the replicas 1 and 3, are transmitted to the drive circuits as the control signals 1 through 8, and thereby the output impedance is set equal to the resistance value of the resistor RQ.

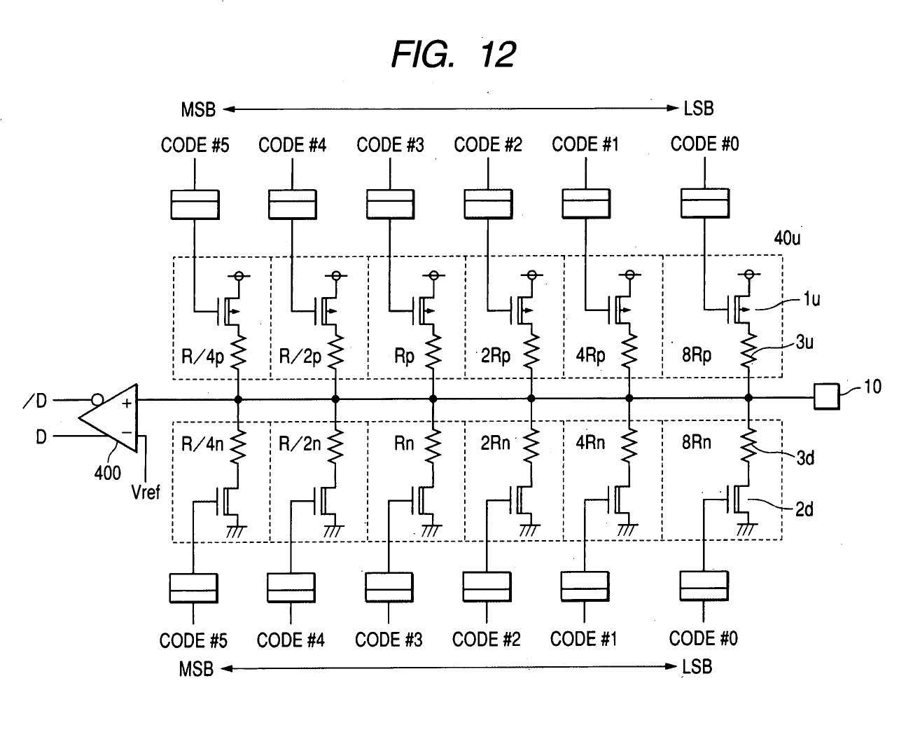

A circuit diagram illustrating one embodiment of an output circuit according to the present invention is shown in FIG. 12. A terminating resistance employed in the present embodiment is formed in such a manner that resistance values have binary weights inclusive of MOSFETs and resistive elements connected thereto. The present embodiment shows an example controlled by impedance control codes of 6 bits. That is, resistance values are set as 8Rp, 8Rn, 4Rp, 4Rn, 2Rp, 2Rn, Rp, Rn, Rp/2, Rn/2, Rp/4 and Rn/4 in association with binary codes of 6 bits comprising a code #0 (LSB), a code #1, a code #2, a code #3, a code #4 and a code #5 (MSB). The codes #0 through #5 are respectively fetched into latch circuits and codes fetched into the latch circuits are transmitted to the gates of the P channel and N channel MOSFETs. Incidentally, an output circuit set so as to have the maximum output impedance as an output circuit as in the unit output circuit (0) shown in FIG. 5 is omitted.

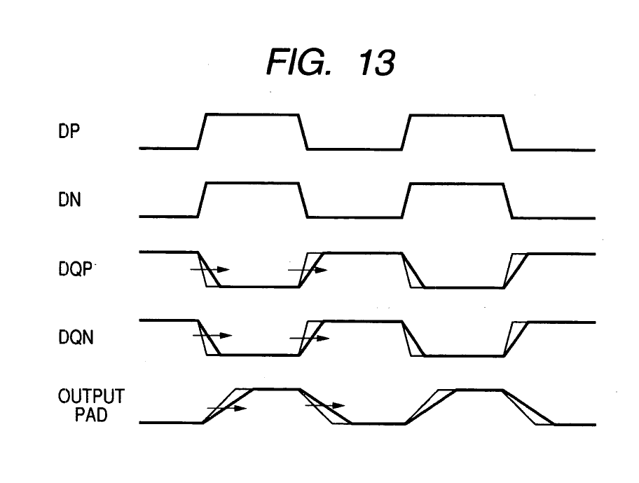

A waveform diagram for describing the output operation of the output circuit according to the present invention is shown in FIG. 13. In response to changes in output data DP and DN, drive circuits DVP and DVN adjust drive currents in accordance with the control signals SP1 and SP2 and SN1 and SN2. These drive circuits DVP and DVN are set identical in circuit configuration and similarly change drive signals DQP and DQN in response to the control signals SP1 and SP2 and SN1 and SN2. The input capacitance of the output circuit is set such that both input capacitances of the P channel and N channel output MOSFETs are made equal to each other. Thus, when the drive signals DQP and DQN respectively fall to a low level, the N channel output MOSFET is brought into an off state and the P channel output MOSFET is brought into an on state, so that a change in signal at the output terminal PAD takes place. On the other hand, when the drive signals DQP and DQN respectively rise to a high level, the P channel output MOSFET is brought into the off state and the N channel output MOSFET is brought into the on state, so that a change in signal at the output terminal PAD occurs.

Such changes in signal at the output terminal PAD occur in the following manner. Since the drive currents are formed in the same manner by the drive circuits DVP and DVN, and the input capacitance of the output circuit is set such that both input capacitances of the P channel and N channel output MOSs are made equal to each other, the rising and falling edges at the output terminal PAD change with similar delay times even though adjustments to through rates are made by the control signals SP1 and SP2 and SN1 and SN2. As a result, data validity periods can be prolonged equally as in the case of a high level period with a midpoint voltage (VDDQ/2) as the reference, a low level period and the DQ output (A) shown in FIG. 8. In other words, the times Δt taken for variations in the output rising edge/falling edge such as shown in the DQ outputs (B) and (C) of FIG. 8 can be set to approximately zero.

As described above, the output circuit according to the invention of the present application is characterized in that the dummy MOSFETs are added to the output NMOS side so as to become identical to the output PMOSs in gate capacitance. As a result, the gate capacitances on the output PMOS and NMOS sides become equal to each other, and the output MOSs are driven by the similar drive currents, thereby to make it possible to make equal the times required for their gates to be charged/discharged as well, whereby the data validity period can be prolonged. Setting the drive circuits for driving the output NMOSs and PMOSs to the same configuration as described above makes it possible to lighten an influence exerted on the data validity period by the fact that device process variations occur similarly.

When the drive capacities at the drive circuits are switched to make a reduction in drive capacity, the gate of the corresponding output MOSFET is gently charged/discharged, and hence di/dt of an output MOSFET current can be reduced, thereby enabling a contribution to a reduction in output noise. When the drive capacity is set large, the delay time of the output can be reduced. That is, the optimum through rate can be set in accordance with load capacity. By independently adjusting the drive capacities of the drive circuit on the output NMOS side and the drive circuit on the output PMOS side even when variations occur in the output rise and fall times, high-precision adjustments for reductions in variations are enabled.

The output impedance is adjusted to match the output impedance of the output circuit to the characteristic impedance of a transmission line. Therefore, when the semiconductor integrated circuit device according to the present invention is mounted in a system, re-reflection noise can be absorbed through the output impedance even though no terminating resistor is provided at an input terminal of a semiconductor integrated circuit device that belongs to the other party which performs signal transmission. It is therefore possible to transfer data at a high frequency.

While the invention made above by the present inventors has been described specifically on the basis of the preferred embodiments, the present invention is not limited to the embodiments referred to above. It is needless to say that various changes can be made thereto within the scope not departing from the gist thereof. For instance, there may be adopted one in which the circuit for adjusting the output impedance or the circuit for adjusting the through rate is omitted. The dummy capacitance may be one having a device structure substantially equivalent to a MOSFET in addition to one using the above MOSFETs. For example, it may be configured without providing the source and drain regions. The present invention can be widely used in various semiconductor integrated circuit devices each provided with an output circuit which performs a high speed output operation, as well as in a high-speed semiconductor memory.

What is claimed is:

1. A semiconductor integrated circuit device comprising:
an N channel output MOSFET;
a P channel output MOSFET; and
a dummy MOSFET having a gate connected to a gate of the N channel output MOSFET,
wherein the dummy MOSFET has a gate capacitance corresponding to a difference between a gate capacitance of the P channel output MOSFET and a gate capacitance of the N channel output MOSFET.

2. The semiconductor integrated circuit device according to claim 1,
wherein the N channel output MOSFET, the P channel output MOSFET and the dummy MOSFET are formed in the same channel width, and
wherein the dummy MOSFET is formed so as to have a gate width corresponding to a difference between gate widths of the N channel output MOSFET and the P channel output MOSFET.

3. The semiconductor integrated circuit device according to claim 2,
wherein the dummy MOSFET comprises an N channel MOSFET and is formed in the same semiconductor region as the N channel output MOSFET,
wherein a source of the N channel output MOSFET is connected to a circuit ground potential,
wherein a source of the P channel output MOSFET is connected to a power supply voltage terminal, and
wherein the dummy MOSFET and the N channel output MOSFET have gate electrodes formed integrally with each other, and source and drain regions of the dummy MOSFET are connected to the circuit ground potential.

4. The semiconductor integrated circuit device according to claim 2,
wherein the dummy MOSFET comprises a P channel MOSFET,
wherein a source of the N channel output MOSFET is connected to a circuit ground potential,
wherein a source of the P channel output MOSFET is connected to a power supply voltage terminal, and
wherein the dummy MOSFET and the N channel output MOSFET have gate electrodes formed integrally with each other, and source and drain regions of the dummy MOSFET are connected to the power supply voltage terminal.

5. The semiconductor integrated circuit device according to claim 3,
wherein the P channel output MOSFET, the N channel output MOSFET and the dummy MOSFET further include a first resistive element and a second resistive element,
wherein a drain of the P channel output MOSFET is connected to an output line via the first resistive element to configure a first unit output circuit,
wherein a drain of the N channel output MOSFET is connected to an output line via the second resistive element to configure a second unit output circuit,
wherein the number of each of the first and second unit output circuits is plural,
wherein the first unit output circuits constitute a first output circuit in which the number of the first unit output circuits operated based on a first output impedance control signal is controlled to form an output signal of one level, and
wherein the second unit output circuits constitute a second output circuit in which the number of the second unit output circuits operated based on a second output impedance control signal is controlled to form an output signal of the other level.

6. The semiconductor integrated circuit device according to claim 5,
wherein the first and second output impedance control signals are generated by an output impedance control signal generator,
wherein the output impedance control signal generator comprises a first circuit and a second circuit,
wherein the first circuit is connected between an external terminal and a circuit ground potential and performs impedance comparisons between a resistive element set so as to have a resistance value equivalent to a characteristic impedance of a transmission line for transmitting the output signal, and a first replica circuit equivalent to the first output circuit to thereby generate the first output impedance control signal for the first output circuit, and
wherein the second circuit performs impedance comparisons between the resistive element and a second replica circuit equivalent to the second output circuit to thereby generate the second output impedance control signal for the second output circuit.

7. The semiconductor integrated circuit device according to claim 6, further including drive circuits respectively provided in a one-to-one correspondence with the first unit output circuits and the second unit output circuits and set to the same circuit configuration,
wherein the drive circuits include first and second drive circuits having tristate output functions, each of which has an input and an output connected in common, and the operations of the first and second drive circuits are selectively performed in response to output through rate control signals and the first or second output impedance control signal.

8. The semiconductor integrated circuit device according to claim 7, wherein the output through rate control signals are formed by non-volatile memory means.
